(19) United States
(12) Patent Application Publication
(10) Pub. No.: US 2022/0367729 A1
(43) Pub. Date: Nov. 17, 2022

(54) SEMICONDUCTOR ELEMENT-USING MEMORY DEVICE

(71) Applicant: Unisantis Electronics Singapore Pte. Ltd., Singapore (SG)

(72) Inventors: Nozomu HARADA, Tokyo (JP); Koji SAKUI, Tokyo (JP)

(21) Appl. No.: 17/740,723

(22) Filed: May 10, 2022

(30) Foreign Application Priority Data
May 13, 2021 (JP) PCT/JP2021/018243

(51) Int. Cl. H01L 29/786; H01L 21/8238; H01L 27/12

(52) U.S. Cl. CPC H01L 29/78642; H01L 21/823885; H01L 27/1203

(57) ABSTRACT

On a substrate, an N⁺ layer connecting to a source line SL, a first Si pillar standing in a perpendicular direction, and a second Si pillar on the first Si pillar are disposed. In a central portion of the first Si pillar, a P⁺ layer is disposed, and a P layer is disposed so as to surround the P⁺ layer. In a central portion of the second Si pillar, a P⁺ layer is disposed, and a P layer is disposed so as to surround the P⁺ layer. On the second Si pillar, an N⁺ layer is disposed so as to connect to a bit line BL. A first gate insulating layer is disposed so as to surround the first Si pillar, and a second gate insulating layer is disposed so as to surround the second Si pillar. A first gate conductor layer is disposed so as to surround the first insulating layer and to connect to a plate line PL, and a second gate conductor layer is disposed so as to surround the second insulating layer and to connect to a word line WL. Voltages applied to the source line SL, the plate line PL, the word line WL, and the bit line BL are controlled, to perform a data retention operation of retaining a hole group generated within a channel region due to an impact ionization phenomenon or a gate induced drain leakage current and a data erase operation of discharging the hole group from within the channel region.

### CROSS-REFERENCE TO RELATED APPLICATIONS

This application claims priority to PCT/JP2021/018243 filed May 13, 2021, the enter content of which is incorporated herein by reference.

### TECHNICAL FIELD

The present invention relates to a semiconductor-element-using memory device.

### BACKGROUND ART

In recent years, in development of the LSI (Large Scale Integration) technology, there has been a demand for memory elements having a higher degree of integration and higher performance.

In the ordinary planar MOS transistor, the channel extends, along the upper surface of the semiconductor substrate, in the horizontal direction. By contrast, the channel of the SGT extends in a direction perpendicular to the upper surface of the semiconductor substrate (refer to, for example, Patent Literature 1 and Non Patent Literature 1). For this reason, the SGT enables, compared with the planar MOS transistor, an increase in the density of the semiconductor device. Use of this SGT as a select transistor enables a higher degree of integration in, for example, a DRAM (Dynamic Random Access Memory, refer to, for example, Non Patent Literature 2) to which a capacitor is connected, a PCM (Phase Change Memory, refer to, for example, Non Patent Literature 3) to which a resistance change element is connected, an RRAM (Resistive Random Access Memory, refer to, for example, Non Patent Literature 4), and an MRAM (Magneto-resistive Random Access Memory, refer to, for example, Non Patent Literature 5) in which a current is used to change the orientation of the magnetic spin to change the resistance. In addition, there is a capacitor-less DRAM memory cell constituted by a single MOS transistor (refer to Non Patent Literature 6), for example. The present application relates to a dynamic flash memory that does not include resistance change elements or capacitors and can be constituted by a MOS transistor alone.

For the above-described capacitor-less DRAM memory cell constituted by a single MOS transistor, FIGS. 7A to 7D illustrate the write operation, FIGS. 8A and 8B illustrate a problem in the operation, and FIGS. 9A to 9C illustrate the read operation (refer to Non Patent Literatures 7 to 10).

FIGS. 7A to 7D illustrate the write operation of the DRAM memory cell. FIG. 7A illustrates the “1” write state. This memory cell is formed on an SOI substrate 101, and is constituted by a source N⁺ layer 103 (hereafter, semiconductor regions containing donor impurities at high concentrations will be referred to as “N⁺ layers”) to which a source line SL is connected, a drain N⁺ layer 104 to which a bit line BL is connected, a gate conductive layer 105 to which a word line WL is connected, and a floating body (Floating Body) 102 of a MOS transistor 110a; thus, the capacitor-less DRAM memory cell is constituted by the single MOS transistor 110a. Note that the floating body 102 is in contact with the immediately underlying layer, the SiO₂ layer 101 of the SOI substrate. In the memory cell constituted by the single MOS transistor 110a, in order to write “1”, the MOS transistor 110a is operated in the saturation region. Specifically, an electron channel 107 extending from the source N⁺ layer 103 has a pinch-off point 108 and does not reach the drain N⁺ layer 104 to which the bit line is connected. Thus, when the MOS transistor 110a is operated such that the bit line BL connected to the drain N⁺ layer 104 and the word line WL connected to the gate conductive layer 105 are set at high voltages, and the gate voltage is set at about ½ of the drain voltage, the electric field strength becomes maximum at the pinch-off point 108 near the drain N⁺ layer 104. As a result, accelerated electrons flowing from the source N⁺ layer 103 to the drain N⁺ layer 104 collide with the Si lattice, and the kinetic energy lost at this time causes generation of electron-hole pairs (impact ionization phenomenon). Most of the generated electrons (not shown) reach the drain N⁺ layer 104. A very small portion of the electrons, very hot electrons jump over a gate oxide film 109, to reach the gate conductive layer 105. Holes 106 generated at the same time charge the floating body 102. In this case, the generated holes contribute, in the floating body 102 formed of P-type Si, as an increment of the majority carrier. When the floating body 102 is filled with the generated holes 106 and the voltage of the floating body 102 becomes higher than that of the source N⁺ layer 103 by Vb or more, holes further generated are discharged to the source N⁺ layer 103. Vb is the built-in voltage of the PN junction between the source N⁺ layer 103 and the P-layer floating body 102, and is about 0.7 V. FIG. 7B illustrates a state in which the floating body 102 is charged to saturation with the holes 106 generated.

Hereinafter, with reference to FIG. 7C, the “0” write operation of the memory cell 110 will be described. For the common select word line WL, there are randomly a memory cell 110a to which “1” is written and a memory cell 110b to which “0” is written. FIG. 7C illustrates a state of a rewrite from a “1” write state to a “0” write state. In order to write “0”, the voltage of the bit line BL is set to a negative bias and the PN junction between the drain N⁺ layer 104 and the P-layer floating body 102 is forward biased. As a result, the holes 106 generated in advance in the floating body 102 in the previous cycle flow to the drain N⁺ layer 104 connected to the bit line BL. Completion of the write operation provides two states of memory cells that are the memory cell 110a filled with the generated holes 106 (FIG. 7B) and the memory cell 110b from which the generated holes have been discharged (FIG. 7C). In the memory cell 110a filled with the holes 106, the floating body 102 has a higher potential than the floating body 102 not having generated holes. Thus, the threshold voltage of the memory cell 110a becomes lower than the threshold voltage of the memory cell 110b. This state is illustrated in FIG. 7D.

Hereinafter, a problem in the operation of the memory cell constituted by a single MOS transistor will be described with reference to FIGS. 8A and 8B. As illustrated in FIG. 8A, the capacitance C_{FB} of the floating body 102 is the sum of the capacitance C_{WL} between the gate to which the word line is connected and the floating body 102, the junction capacitance C_{SL} of the PN junction between the source N⁺ layer 103 to which the source line is connected and the floating body 102, and the junction capacitance C_{BL} of the PN junction between the drain N⁺ layer 103 to which the bit line is connected and the floating body 102, and is expressed as follows.

C_{FB}=C_{WL}+C_{BL}+C_{SL} (1)

Thus, a change in the word line voltage V_{WL} at the time of writing affects the voltage of the floating body 102 serving as the storage node (contact point) of the memory cell. This state is illustrated in FIG. 8B. At the time of writing, an increase in the word line voltage V_{WL} from 0 V to V_{ProgrWL} results in an increase in the voltage V_{FB} of the floating body 102 from the initial voltage V_{FB1} of the original word line voltage to V_{FB2} due to capacitive coupling with the word line. The voltage change amount ΔV_{FB} is expressed as follows:

ΔV_{FB}=V_{FB2}−V_{FB1}=C_{WL}/(C_{WL}+C_{BL}+C_{SL})×V_{ProgWL} (2)

where

β=C_{WL}/(C_{WL}+C_{BL}+C_{SL}) (3)

is expressed and β is referred to as a coupling ratio. In such a memory cell, Cm, has a high contribution ratio and, for example, C_{WL}:C_{BL}:C_{SL}=8:1:1. In this case, β=0.8. When the word line changes, for example, from 5 V at the time of writing to 0 V at the end of writing, the capacitive coupling between the word line and the floating body 102 causes an amplitude noise as much as 5V×β=4 V on the floating body 102. Thus, the potential difference margin is not sufficiently provided between the “1” potential and the “0” potential of the floating body at the time of writing, which is a problem.

FIGS. 9A to 9C illustrate the read operation. FIG. 9A illustrates the “1” write state, and FIG. 9B illustrates the “0” write state. However, actually, even when “1” is written to write Vb in the floating body 102, returning of the word line to 0 V upon completion of writing brings the floating body 102 to a negative bias. When “0” is written, lowering to a further negative bias is caused, so that, as illustrated in FIG. 9C, at the time of writing, the potential difference margin between “1” and “0” cannot be made sufficiently large. This small operation margin is a major problem of the DRAM memory cell. In addition, an increase in the density of the DRAM memory cell needs to be achieved.

### CITATION LIST

### Patent Literature

[PTL 1] Japanese Unexamined Patent Application Publication No. 2-188966

### Non Patent Literature

[NPL 1] Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)
[NPL 2] H. Chung, H. Kim, H. Kim, K. Kim, S. Kim, K. Dong, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference, (2011)
[NPL 3] H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol. 98, No 12, December, pp. 2201-2227 (2010)
[NPL 4] T. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V,” IEDM (2007)
[NPL 5] W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9 (2015)
[NPL 6] M. G. Ertosum, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010)
[NPL 7] J. Wan, L. Rojer, A. Zaslaysky, and S. Critoloveanu: “A Compact Capacitor-Less High-Speed DRAM Using Field Effect-Controlled Charge Regeneration,” Electron Device Letters, Vol. 35, No. 2, pp. 179-181 (2012)
[NPL 8] T. Ohsawa, K. Fujita, T. Higashi, Y. Iwata, T. Kajiyama, Y. Asao, and K. Sunouchi: “Memory design using a one-transistor gain cell on SOI,” IEEE JSSC, vol. 37, No. 11, pp 1510-1522 (2002).
[NPL 9] T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond,” IEEE IEDM (2006).
[NPL 10] E. Yoshida, T. Tanaka: “A Design of a Capacitorless 1T-DRAM Cell Using Gate-induced Drain Leakage (GIDL) Current for Low-power and High-speed Embedded Memory,” IEEE IEDM (2003).
[NPL 11] J. Y. Song, W. Y. Choi, J. H. Park, J. D. Lee, and B-G. Park: “Design Optimization of Gate-All-Around (GAA) MOSFETs,” IEEE Trans. Electron Devices, vol. 5, no. 3, pp. 186-191, May 2006.
[NPL 12] N. Loubet, et al.: “Stacked Nanosheet Gate-All-Around Transistor to Enable Scaling Beyond FinFET,” 2017 IEEE Symposium on VLSI Technology Digest of Technical Papers, T17-5, T230-T231, June 2017.
[NPL 13] H. Jiang, N. Xu, B. Chen, L. Zengl, Y. He, G. Du, X. Liu and X. Zhang: “Experimental investigation of self heating effect (SHE) in multiple-fin SOI FinFETs,” Semicond. Sci. Technol. 29 (2014) 115021 (7pp).
[NPL 14] E. Yoshida, and T. Tanaka: “A Capacitorless 1T-DRAM Technology Using Gate-Induced Drain-Leakage (GIDL) Current for Low-Power and High-Speed Embedded Memory,” IEEE Transactions on Electron Devices, Vol. 53, No. 4, pp. 692-697, April 2006.

### SUMMARY OF INVENTION

### Technical Problem

In an SGT-using memory device that is a capacitor-less single-transistor DRAM (gain cell), capacitive coupling between the word line and the floating-state SGT body is strong; at the time of reading or writing of data, a change in the potential of the word line is transmitted directly as noise to the SGT body, which has been problematic. This causes problems of erroneous reading or erroneous writing of storage data and makes it difficult to put the capacitor-less single-transistor DRAM (gain cell) into practical use. The above-described problems need to be addressed and DRAM memory cells having higher performance and higher density need to be provided.

### Solution to Problem

In order to address such problems, a semiconductor-element-using memory device according to the present invention includes:

a first semiconductor base disposed on a substrate so as to, relative to the substrate, stand in a perpendicular direction or extend in a horizontal direction, and including a first impurity layer disposed in a region at least including a central portion of a cross section, and a second impurity layer covering the first impurity layer and having a lower impurity concentration than the first impurity layer;

a second semiconductor base connecting to the first semiconductor base;

a first gate insulating layer surrounding a portion of or an entirety of a one-end side surface of the first semiconductor base;

a second gate insulating layer connecting to the first gate insulating layer and surrounding a portion of or an entirety of a side surface of the second semiconductor base;

a first gate conductor layer covering the first gate insulating layer;

a second gate conductor layer covering the second gate insulating layer;

a third impurity layer connecting to the first semiconductor base and having a conductivity opposite to a conductivity of the first semiconductor base; and

a fourth impurity layer connecting to the second semiconductor base and having a conductivity opposite to a conductivity of the second semiconductor base,

wherein voltages applied to the third impurity layer, the fourth impurity layer, the first gate conductor layer, and the second gate conductor layer are controlled to perform a memory write operation, a memory read operation, and a memory erase operation (first invention).

In the first invention, the second semiconductor base includes a fifth impurity layer disposed in a region at least including a central portion in a cross section, and a sixth impurity layer covering the fifth impurity layer, having the same conductive polarity as the fifth impurity layer, and having a lower impurity concentration than the fifth impurity layer (second invention).

In the first invention, the second semiconductor base is formed of a seventh impurity layer having a lower impurity concentration than the first impurity layer (third invention).

In the third invention, when viewed from a central-axis direction, an outer peripheral line of the first semiconductor base is disposed outside relative to an outer peripheral line of the second semiconductor base (fourth invention).

In the first invention, a first gate capacitance between the first gate conductor layer and the first semiconductor base is higher than a second gate capacitance between the second gate conductor layer and the second semiconductor base (fifth invention).

In the first invention, voltages applied to the third impurity layer, the fourth impurity layer, the first gate conductor layer, and the second gate conductor layer are controlled to perform an operation of causing an impact ionization phenomenon due to a current flowing between the third impurity layer and the fourth impurity layer or a gate induced drain leakage current to generate an electron group and a hole group within a channel region constituted by the first semiconductor base and the second semiconductor base, an operation of discharging, of the generated electron group and hole group, the electron group or hole group serving as a minority carrier in the first semiconductor base and the second semiconductor base, and an operation of causing a portion of or an entirety of the electron group and hole group serving as a majority carrier in the first semiconductor base and the second semiconductor base to remain at least in the first semiconductor base, to perform the memory write operation, and

voltages applied to the third impurity layer, the fourth impurity layer, the first gate conductor layer, and the second gate conductor layer are controlled to remove the electron group or hole group remaining and serving as a majority carrier in the first semiconductor base and the second semiconductor base, to perform the memory erase operation (sixth invention).

### BRIEF DESCRIPTION OF DRAWINGS

FIG. 1 is a structural view of an SGT-including memory device according to a first embodiment.

FIGS. 2A, 2B, and 2C include explanatory views of the erase operation mechanism of an SGT-including memory device according to a first embodiment.

FIGS. 3A, 3B, and 3C include explanatory views of the write operation mechanism of an SGT-including memory device according to a first embodiment.

FIGS. 4AA, 4AB, and 4AC include explanatory views of the read operation mechanism of an SGT-including memory device according to a first embodiment.

FIGS. 4BA, 4BB, 4BC, and 4BD include explanatory views of the read operation mechanism of an SGT-including memory device according to a first embodiment.

FIG. 5 is a structural view of an SGT-including memory device according to a second embodiment.

FIG. 6 is a structural view of an SGT-including memory device according to a third embodiment.

FIGS. 7A, 7B, 7C, and 7D include explanatory views of a problem in the operation of a related-art capacitor-less DRAM memory cell.

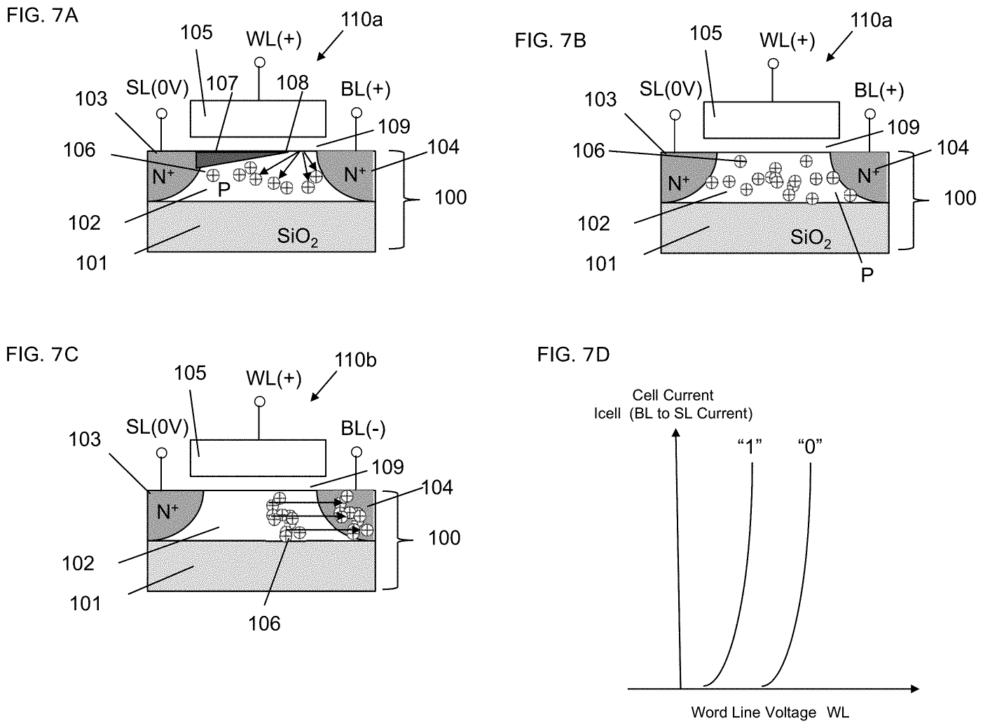

FIGS. 8A and 8B include explanatory views of a problem in the operation of a related-art capacitor-less DRAM memory cell.

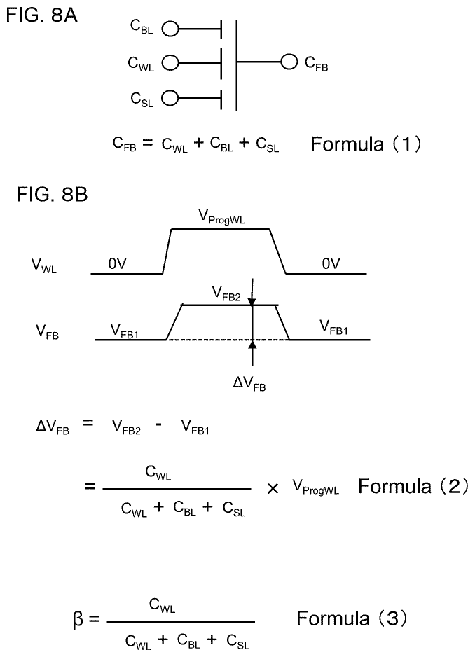

FIGS. 9A, 9B, and 9C illustrate the read operation of a related-art capacitor-less DRAM memory cell.

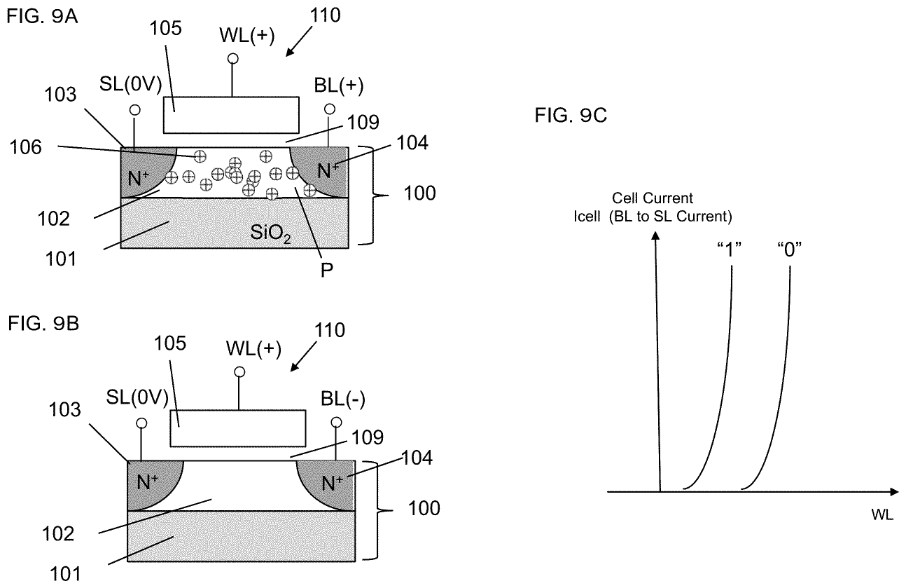

### DESCRIPTION OF EMBODIMENTS

Hereinafter, a semiconductor-element-using memory device (hereafter, referred to as a dynamic flash memory) according to the present invention will be described in terms of structures, driving operations, and production methods with reference to drawings.

### First Embodiment

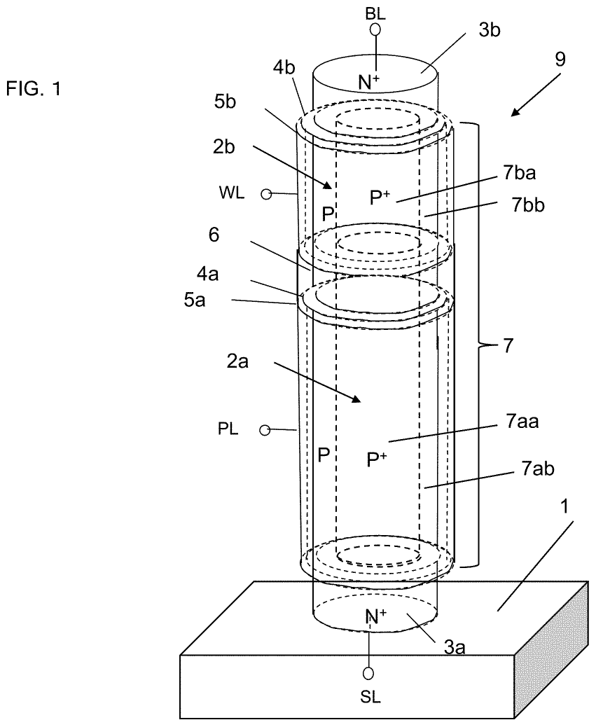

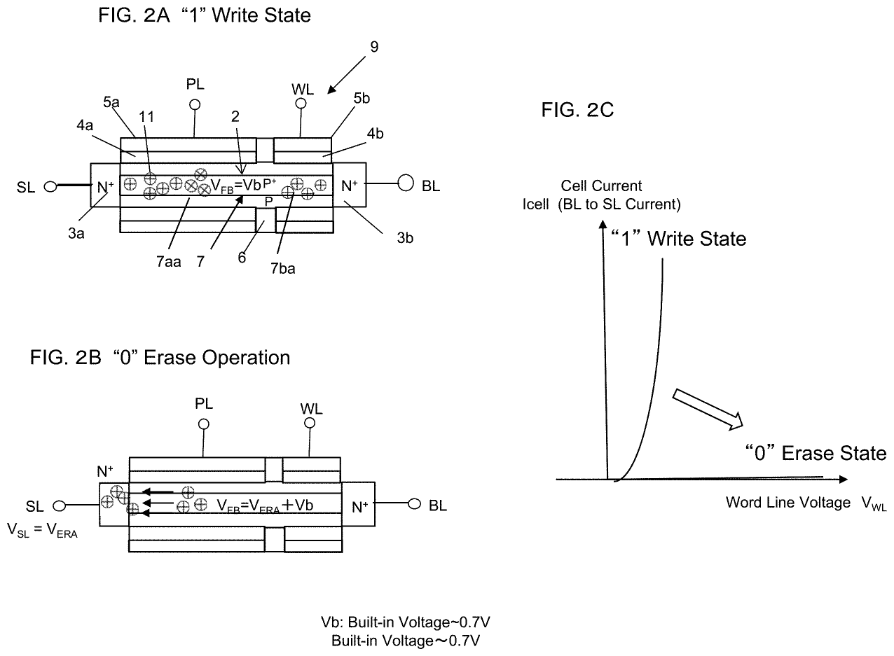

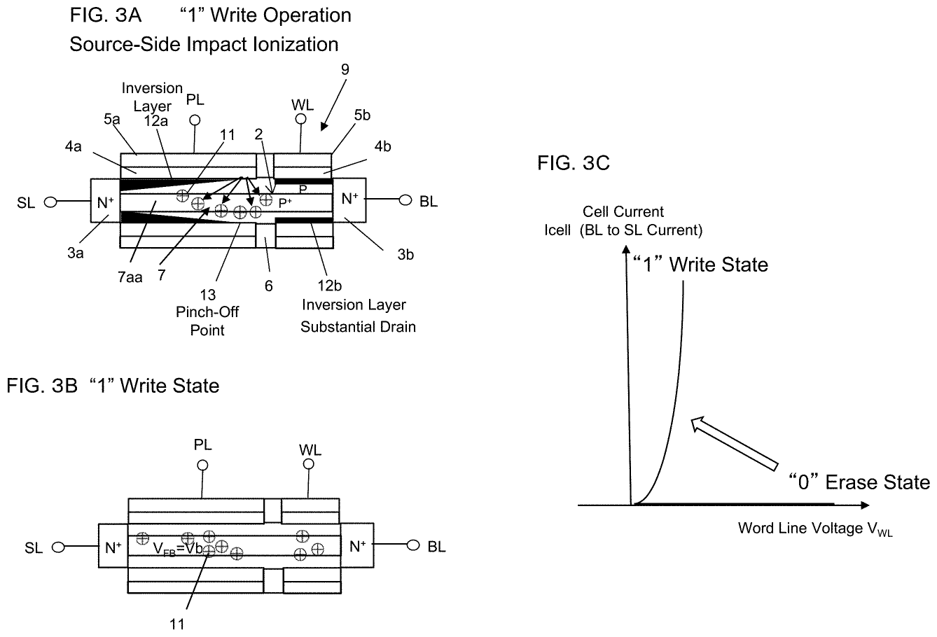

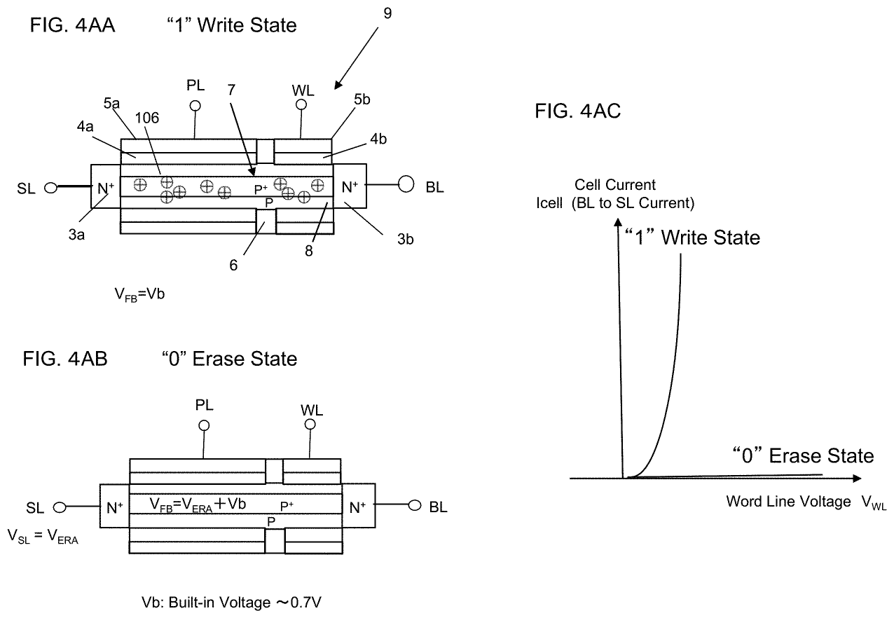

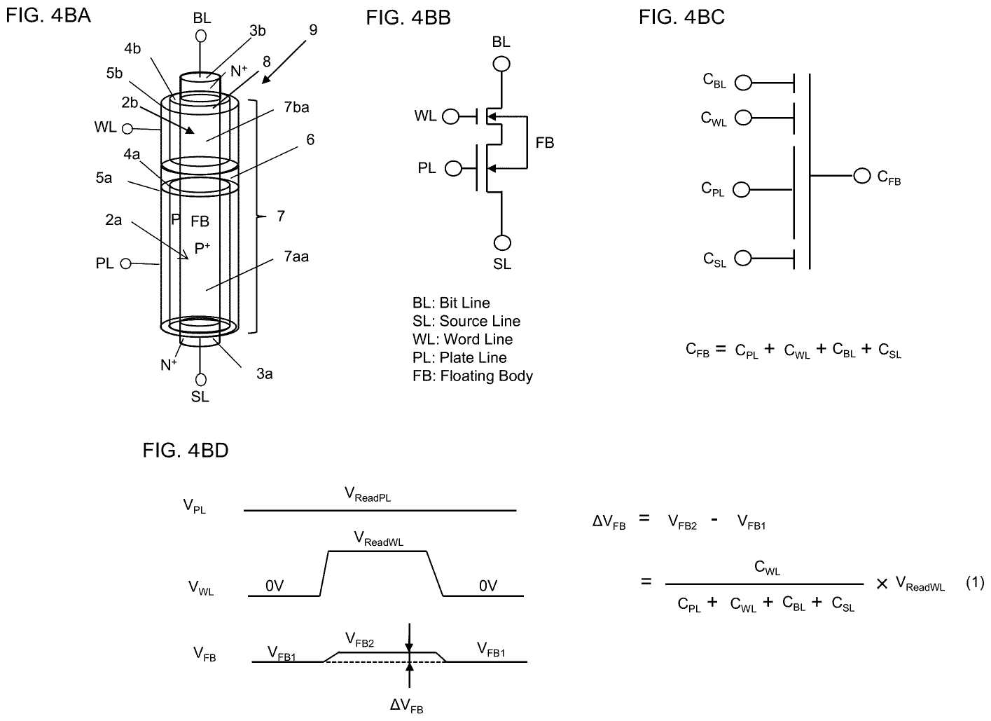

FIG. 1 to FIGS. 4BA-4BD will be used to describe a dynamic flash memory cell according to a first embodiment of the present invention in terms of structures, operation mechanisms, and production methods. FIG. 1 will be used to describe the structure of the dynamic flash memory cell. Subsequently, FIGS. 2A to 2C will be used to describe the data erase mechanism; FIGS. 3A to 3C will be used to describe the data write mechanism; FIGS. 4AA to 4BD will be used to describe the data write mechanism.

FIG. 1 illustrates the structure of a dynamic flash memory cell according to the first embodiment of the present invention. On a substrate 1 (serving as an example of “substrate” in CLAIMS), an N⁺ layer 3a (serving as an example of “third impurity layer” in CLAIMS) is disposed. On the N⁺ layer 3a, a first silicon semiconductor pillar 2a (serving as an example of “first semiconductor base” in CLAIMS) (hereafter, silicon semiconductor pillars will be referred to as “Si pillars”) is disposed, which is overlain by a second Si pillar 2b (serving as an example of “second semiconductor base” in CLAIMS). In the first Si pillar 2a, in plan view, the central portion is a P⁺ layer 7aa (serving as an example of “first impurity layer” in CLAIMS) (hereafter, semiconductor regions having a conductivity opposite to that of N⁺ layers and containing acceptor impurities at high concentrations will be referred to as “P⁺ layers”); surrounding the P⁺ layer 7aa, a P layer lab (serving as an example of “second impurity layer” in CLAIMS) having a lower acceptor impurity concentration than the P⁺ layer 7aa is disposed. Similarly, in the second Si pillar 2b, in plan view, the central portion is a P⁺ layer 7ba (serving as an example of “fifth impurity layer” in CLAIMS); surrounding the P⁺ layer 7ba, a P layer 7bb (serving as an example of “sixth impurity layer” in CLAIMS) having a lower acceptor impurity concentration than the P⁺ layer 7ba is disposed. On the second Si pillar 2b, an N⁺ layer 3b (serving as an example of “fourth impurity layer” in CLAIMS) is disposed. The regions of the Si pillars 2a and 2b between the N⁺ layers 3a and 3b serve as a channel region 7 (serving as an example of “channel region” in CLAIMS). Surrounding the first Si pillar 2a, a first gate insulating layer 4a (serving as an example of “first gate insulating layer” in CLAIMS) is disposed; surrounding the second Si pillar 2b, a second gate insulating layer 4b (serving as an example of “second gate insulating layer” in CLAIMS) is disposed. Surrounding the first gate insulating layer 4a, a first gate conductor layer 5a (serving as an example of “first gate conductor layer” in CLAIMS) is disposed; surrounding the second gate insulating layer 4b, a second gate conductor layer 5b (serving as an example of “second gate conductor layer” in CLAIMS) is disposed. The first gate conductor layer 5a and the second gate conductor layer 5b are isolated from each other by an insulating layer 6. Thus, the N⁺ layers 3a and 3b, the first Si pillar 2a, the second Si pillar 2b, the first gate insulating layer 4a, the second gate insulating layer 4b, the first gate conductor layer 5a, and the second gate conductor layer 5b form a dynamic flash memory cell 9. The N⁺ layer 3a connects to a source line SL (serving as an example of “source line” in CLAIMS); the N⁺ layer 3b connects to a bit line BL (serving as an example of “bit line” in CLAIMS); the first gate conductor layer 5a connects to a plate line PL (serving as an example of “first driving control line” in CLAIMS); the second gate conductor layer 5b connects to a word line WL (serving as an example of “word line” in CLAIMS). A structure is desirably provided such that the gate capacitance of the first gate conductor layer 5a connecting to the plate line PL is higher than the gate capacitance of the second gate conductor layer 5b connecting to the word line WL. In the memory device, a plurality of the dynamic flash memory cells are arranged in a two-dimensional array on the substrate 1.

Note that, in FIG. 1, in order to make the gate capacitance of the first gate conductor layer 5a connected to the plate line PL be higher than the gate capacitance of the second gate conductor layer 5b to which the word line WL is connected, the gate length of the first gate conductor layer 5a is made larger than the gate length of the second gate conductor layer 5b. However, alternatively, without making the gate length of the first gate conductor layer 5a be larger than the gate length of the second gate conductor layer 5b, the film thickness of the gate insulating film of the first gate insulating layer 4a may be made smaller than the film thickness of the gate insulating film of the second gate insulating layer 4b. Alternatively, the dielectric constant of the first gate insulating layer 4a may be made larger than the dielectric constant of the second gate insulating layer 4b. Alternatively, a combination of some of the lengths of the gate conductor layers 5a and 5b and the film thicknesses and the dielectric constants of the gate insulating layers 4a and 4b may be selected such that the gate capacitance of the first gate conductor layer 5a is made higher than the gate capacitance of the second gate conductor layer 5b.

The first gate conductor layer 5a may be divided into two or more portions, and the portions may be operated, as conductive electrodes of the plate line, synchronously or asynchronously. Similarly, the second gate conductor layer 5b may be divided into two or more portions, and the portions may be operated, as conductive electrodes of the word line, synchronously or asynchronously. In this case, also, the dynamic flash memory operation is performed. The P layer 7ab does not necessarily cover the entirety of the P⁺ layer 7aa as long as the P layer 7ab continuously extends in the channel direction. The P layer 7bb does not necessarily cover the entirety of the P⁺ layer 7ba as long as the P layer 7bb continuously extends in the channel direction.

Referring to FIGS. 2A to 2C, the erase operation mechanism will be described. The channel region 7 between the N⁺ layers 3a and 3b is electrically isolated from the substrate to serve as a floating body. FIG. 2A illustrates a state in which, prior to the erase operation, a hole group 11 generated by impact ionization in the previous cycle is stored in the channel region 7. The P⁺ layers 7aa and 7ba have higher acceptor impurity concentrations than the P layers 7ab and 7bb, so that the hole group 11 is stored mainly in the P⁺ layers 7aa and 7ba. As illustrated in FIG. 2B, at the time of the erase operation, the voltage of the source line SL is set to a negative voltage V_{ERA}. V_{ERA} is, for example, −3 V. As a result, irrespective of the initial potential value of the channel region 7, the PN junction between the N⁺ layer 3a to which the source line SL is connected and which serves as the source and the channel region 7 is forward biased. As a result, the hole group 11 generated in the previous cycle by impact ionization and stored in the channel region 7 is drawn into the N⁺ layer 3a serving as the source region, and the potential V_{FB} of the channel region 7 becomes V_{FB}=V_{ERA}+Vb where Vb is the built-in voltage of the PN junction and is about 0.7 V. Thus, when V_{ERA}=−3 V, the potential of the channel region 7 becomes −2.3 V. This value corresponds to the potential state of the channel region 7 in an erase state. Thus, when the potential of the channel region 7 of the floating body becomes a negative voltage, the threshold voltage of the N channel MOS transistor of the dynamic flash memory cell 9 increases due to the substrate bias effect. This results in, as illustrated in FIG. 2C, an increase in the threshold voltage of the second gate conductor layer 5b to which the word line WL is connected. This erase state of the channel region 7 is assigned to logical storage data “0”. In data reading after the erase operation, the voltage applied to the first gate conductor layer 5a connecting to the plate line PL is set to be higher than the threshold voltage at the time of logical storage data “1” and to be lower than the threshold voltage at the time of logical storage data “0”, to thereby provide, as illustrated in FIG. 2C, a property in which, in spite of setting the word line WL to a high voltage, no current flows. Note that the conditions of voltages applied to the bit line BL, the source line SL, the word line WL, and the plate line PL and the potential of the floating body are examples for performing the erase operation; other operation conditions for performing the erase operation may be employed. For example, a voltage difference may be applied between the bit line BL and the source line SL to perform the erase operation.

FIGS. 3A to 3C illustrate the write operation of the dynamic flash memory cell according to the first embodiment of the present invention. As illustrated in FIG. 3A, for example, 0 V is applied to the N⁺ layer 3a to which the source line SL is connected; for example, 3 V is applied to the N⁺ layer 3b to which the bit line BL is connected; for example, 2 V is applied to the first gate conductor layer 5a to which the plate line PL is connected; for example, 5 V is applied to the second gate conductor layer 5b to which the word line WL is connected. As a result, as illustrated in FIG. 3A, in a first channel region 7a in an inner region relative to the first gate conductor layer 5a to which the plate line PL is connected, a ring-shaped inversion layer 12a is formed mainly in the P layer lab; the first N channel MOS transistor region including the channel region 7 (refer to FIG. 1) surrounded by the first gate conductor layer 5a and the second gate conductor layer 5b is operated in the saturation region. This results in, in the inversion layer 12a in the inner region relative to the first gate conductor layer 5a to which the plate line PL is connected, the presence of a pinch-off point 13. On the other hand, a second N channel MOS transistor region including the channel region 7 (refer to FIG. 1) surrounded by the second gate conductor layer 5b to which the word line WL is connected is operated in the linear region. This results in, in the second channel region 7bb in the inner region relative to the second gate conductor layer 5b to which the word line WL is connected, without the presence of the pinch-off point, formation of an inversion layer 12b over the entire surface. The inversion layer 12b formed over the entire surface in the inner region relative to the second gate conductor layer 5b to which the word line WL is connected serves as substantially the drain of the first N channel MOS transistor region including the first gate conductor layer 5a. As a result, the electric field becomes maximum in the first boundary region of the channel region 7 between the first N channel MOS transistor region including the first gate conductor layer 5a and the second N channel MOS transistor region including the second gate conductor layer 5b that are connected in series and, in this region, an impact ionization phenomenon is caused. This region is a source-side region when viewed from the second N channel MOS transistor region including the second gate conductor layer 5b to which the word line WL is connected, and hence this phenomenon will be referred to as a source-side impact ionization phenomenon. This source-side impact ionization phenomenon causes electrons to flow from the N⁺ layer 3a to which the source line SL is connected to the N⁺ layer 3b to which the bit line BL is connected. Accelerated electrons collide with lattice Si atoms, and the kinetic energy causes generation of electron-hole pairs. The generated electrons partially flow to the first gate conductor layer 5a and the second gate conductor layer 5b, but most of the generated electrons flow to the N⁺ layer 3b to which the bit line BL is connected. In writing of “1”, Gate Induced Drain Leakage (GIDL: Gate Induced Drain Leakage) current may be used to generate electron-hole pairs, to cause the generated hole group to fill the floating body FB (refer to NPL 14).

As illustrated in FIG. 3B, the generated hole group 11 is the majority carrier of the channel region 7 and charges the channel region 7 to a positive bias. The N⁺ layer 3a to which the source line SL is connected is at 0 V, and hence the channel region 7 is charged to the built-in voltage Vb (about 0.7 V) of the PN junction between the N⁺ layer 3a to which the source line SL is connected and the channel region 7. When the channel region 7 is charged to a positive bias, the threshold voltages of the first N channel MOS transistor region and the second N channel MOS transistor region decrease due to the substrate bias effect. This results in, as illustrated in FIG. 3C, a decrease in the threshold voltage of the second N channel MOS transistor region to which the word line WL is connected. This write state of the channel region 7 is assigned to logical storage data “1”. The generated hole group 11 is stored mainly in the P⁺ layers 7aa and 7ba. This provides a stable substrate bias effect.

At the time of the write operation, instead of the first boundary region, at the second boundary region between the N⁺ layer 3a and the channel region 7 or at the third boundary region between the N⁺ layer 3b and the channel region 7, the impact ionization phenomenon or GIDL current may be caused to generate electron-hole pairs, to cause the generated hole group 11 to charge the channel region 7. Note that the conditions of voltages applied to the bit line BL, the source line SL, the word line WL, and the plate line PL are an example for performing the write operation; other operation conditions for performing the write operation may be employed.

Referring to FIGS. 4AA to 4AC and FIGS. 4BA to 4BD, the dynamic flash memory cell according to the first embodiment of the present invention will be described in terms of read operation. Referring to FIG. 4AA to FIG. 4AC, the read operation of the dynamic flash memory cell will be described. As illustrated in FIG. 4AA, charging of the channel region 7 to the built-in voltage Vb (about 0.7 V) results in a decrease in the threshold voltage of the N channel MOS transistor due to the substrate bias effect. This state is assigned to logical storage data “1”. As illustrated in FIG. 4AB, when the memory block selected prior to writing is in an erase state “0” in advance, the channel region 7 is at a floating voltage V_{FB} equal to V_{ERA}+Vb. The write operation causes random storage of write state “1”. This results in, for the word line WL, generation of logical storage data of logical “0” and “1”. As illustrated in FIG. 4AC, the difference between the two threshold voltages for the word line WL is used to perform reading using a sense amplifier. In data reading, the voltage applied to the first gate conductor layer 5a connecting to the plate line PL is set to be higher than the threshold voltage at the time of logical storage data “1” and to be lower than the threshold voltage at the time of logical storage data “0”, to thereby provide, as illustrated in FIG. 4AC, a property in which, in spite of setting the word line WL to a high voltage, no current flows.

Referring to FIG. 4BA to FIG. 4BD, for the dynamic flash memory cell according to the first embodiment of the present invention, at the time of the read operation, the first gate conductor layer 5a and the second gate conductor layer 5b will be described in terms of the magnitude relation of the two gate capacitances and their related operations. The gate capacitance of the second gate conductor layer 5b to which the word line WL connects is desirably designed to be lower than the gate capacitance of the first gate conductor layer 5a to which the plate line PL connects. As illustrated in FIG. 4BA, the perpendicular length of the first gate conductor layer 5a to which the plate line PL connects is made larger than the perpendicular length of the second gate conductor layer 5b to which the word line WL connects, to make the gate capacitance of the second gate conductor layer 5b to which the word line WL connects be lower than the gate capacitance of the first gate conductor layer 5a to which the plate line PL connects. FIG. 4BB illustrates the equivalent circuit of the single cell of the dynamic flash memory in FIG. 4BA. FIG. 4BC illustrates the coupling capacitance relation of the dynamic flash memory where C_{WL} is the capacitance of the second gate conductor layer 5b, C_{PL} is the capacitance of the first gate conductor layer 5a, C_{BL} is the capacitance of the PN junction between the N⁺ layer 3b serving as the drain and the channel region 7, and C_{SL} is the capacitance of the PN junction between the N⁺ layer 3a serving as the source and the channel region 7. As illustrated in FIG. 4BD, when the voltage of the word line WL changes, its operation affects, as noise, the channel region 7. At this time, the potential change ΔV_{FB} of the channel region 7 is expressed as follows.

ΔV_{FB}=C_{WL}/(C_{PL}+C_{WL}+C_{BL}+C_{SL})×V_{ReadWL} (1)

where V_{ReadWL} is the changing potential of the word line WL at the time of reading. As is clear from Formula (1), relative to the total capacitance C_{PL}+C_{WL}+C_{BL}+C_{SL} of the channel region 7, a decrease in the contribution ratio of C_{WL} results in a decrease in ΔV_{FB}. The perpendicular length of the first gate conductor layer 5a to which the plate line PL connects may be made even larger than the perpendicular length of the second gate conductor layer 5b to which the word line WL connects, to thereby achieve, without a decrease in the degree of integration of the memory cell in plan view, a further decrease in ΔV_{FB}. Note that the conditions of voltages applied to the bit line BL, the source line SL, the word line WL, and the plate line PL and the potential of the floating body are examples for performing the read operation; other operation conditions for performing the read operation may be employed.

Note that the dynamic flash memory element having been described in this embodiment at least has a structure satisfying conditions under which the hole group generated by the impact ionization phenomenon or the gate induced drain leakage current is held in the channel region 7. In order to achieve this, the channel region 7 has a floating body structure isolated from the substrate 1. In this case, even in the case of using, for example, one of SGT, the GAA (Gate All Around: for example, refer to NPL 11) technology and the Nanosheet technology (for example, refer to NPL 12) to form the semiconductor base of the channel region so as to extend horizontally relative to the substrate 1, the above-described dynamic flash memory operation can be performed. Alternatively, a device structure using SOI (Silicon On Insulator) may be employed (for example, refer to NPLs 7 to 10). In this device structure, the bottom portion of the channel region is in contact with the insulating layer of the SOI substrate, and another channel region is surrounded by a gate insulating layer and an element-isolation insulating layer. Also, in this structure, the channel region has a floating body structure. Thus, the dynamic flash memory element provided by the embodiment at least satisfies the condition under which the channel region has a floating body structure. Even in the case of a structure in which a Fin transistor (for example, refer to NPL 13) is formed on an SOI substrate, as long as the channel region has a floating body structure, the dynamic flash memory operation can be performed.

Note that, in FIG. 1, the perpendicular length of the first gate conductor layer 5a to which the plate line PL connects is made even larger than the perpendicular length of the first gate conductor layer 5b to which the word line WL connects, to achieve C_{PL}>C_{WL}. However, just adding the plate line PL also lowers the capacitive coupling ratio of the word line WL to the channel region 7 (C_{WL}/(C_{PL}+C_{WL}+C_{BL}+C_{SL})) This results in a decrease in the potential change ΔV_{FB} of the channel region 7 of the floating body.

In FIG. 1, the first gate conductor layer 5a may connect to the word line WL and the second gate conductor layer 5b may connect to the plate line PL. In this case, also, the above-described dynamic flash memory operation can be performed.

For the voltage of the plate line PL, irrespective of operation modes, for example, a fixed voltage of 2 V may be applied. For the voltage of the plate line PL, only at the time of erase, for example, 0 V may be applied. For the voltage of the plate line PL, as long as it is a voltage that satisfies conditions under which the dynamic flash memory operation can be performed, a fixed voltage or a voltage that changes with time may be applied.

FIG. 1 has been described using the first Si pillar 2a and the second Si pillar 2b having perpendicular sections that are rectangular; alternatively, the shapes of these perpendicular sections may be trapezoidal. Alternatively, the perpendicular sections of the Si pillar 2a and the Si pillar 2b may be different and may be respectively rectangular and trapezoidal.

In FIG. 1, even when the first gate conductor layer 5a surrounds a portion of the first gate insulating layer 4a, the dynamic flash memory operation can be performed. Alternatively, even when the first gate conductor layer 5a is divided into a plurality of conductor layers and the layers are driven synchronously or asynchronously, the dynamic flash memory operation can be performed. Similarly, even when the second gate conductor layer 5b is divided into a plurality of conductor layers, and the layers are driven synchronously or asynchronously, the dynamic flash memory operation can be performed.

In FIG. 1, the N⁺ layer 3a may be extended on the substrate 1 so as to have the role of the N layer of the PN junction and to serve also as the wiring conductor layer of the source line SL. To the N⁺ layer 3a, for example, a conductor layer such as a W layer may be connected. To the N⁺ layer 3a disposed outside of the region where a large number of the first Si pillars 2a and the second Si pillars 2b are further arranged in a two-dimensional array, for example, a conductor layer formed of metal or alloy such as a W layer may be connected.

In FIG. 1, also in a structure in which the conductivities of the N⁺ layers 3a and 3b, the P⁺ layers 7aa and 7ba and the P layers lab and 7bb are individually changed so as to have the opposite conductivities, the dynamic flash memory operation is performed. In this case, in the N-type conductivity first Si pillar 2a and second Si pillar 2b, the majority carrier is electrons. Thus, the electron group generated by impact ionization is stored in the channel region 7, to set the “1” state.

This embodiment provides the following features.

### (Feature 1)

For the plate line PL of the dynamic flash memory cell according to the first embodiment of the present invention, when the dynamic flash memory cell performs the write or read operation, the voltage of the word line WL changes up and down. At this time, the plate line PL plays the role of reducing the capacitive coupling ratio between the word line WL and the channel region 7. As a result, during up-and-down changes in the voltage of the word line WL, the effect due to the changes in the voltage in the channel region 7 can be considerably suppressed. As a result, the difference between the threshold voltages for indication of logical “0” and “1” can be made to be large. This leads to an increase in the operation margin of the dynamic flash memory cell.

### (Feature 2)

In this embodiment, the hole group 11 generated by the impact ionization phenomenon is stored mainly in the P⁺ layers 7aa and 7ba. In the read operation, the electronic current flowing between the N⁺ layers 3a and 3b flows through the P layers 7ab and 7bb. Thus, in the read operation, the channel of the electronic current in the P layers 7ab and 7bb is separated from the floating body of the P⁺ layer 7aa and 7ba regions, to thereby retain more stably the floating body voltage. This enables the dynamic flash memory to operate stably, which leads to higher performance.

### Second Embodiment

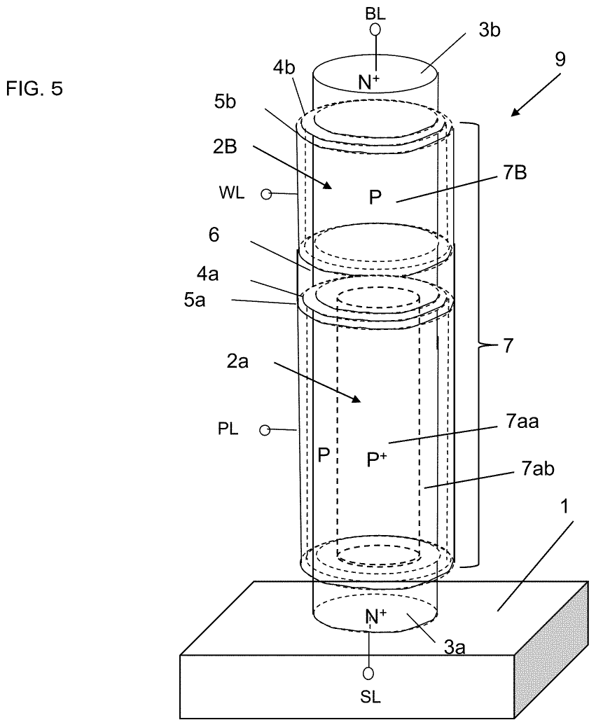

Referring to FIG. 5, the structure of a dynamic flash memory according to a second embodiment will be described. Note that, in the actual memory device, a large number of dynamic flash memory cells 9 are arranged in matrix on a substrate 1. In FIG. 5, the same or similar elements in FIG. 1 are denoted by the same reference signs.

A second Si pillar 2B as a whole serves as a P layer 7B. The other configurations are the same as in FIG. 1. Note that, in the perpendicular direction, the boundary between the P⁺ layer 7aa and the P layer 7B of the Si pillar 2B may be disposed within the insulating layer 6, or in the first Si pillar 2a near the insulating layer 6, or in the second Si pillar 2B.

This embodiment provides the following features.

### (Feature 1)

In this embodiment, the hole group due to writing of “1” data is further stored in the P⁺ layer 7aa within the first Si pillar 2a, compared with the case in FIG. 1. This suppresses variations in the floating body voltage of the P⁺ layer 7aa due to the address pulse voltage applied to the word line WL. This enables the dynamic flash memory to operate with stability.

### (Feature 2)

In this embodiment, the second Si pillar 2B as a whole can be operated as the channel of electronic current for reading “1” or “0”. This provides an increase in the speed of the dynamic flash memory.

### Third Embodiment

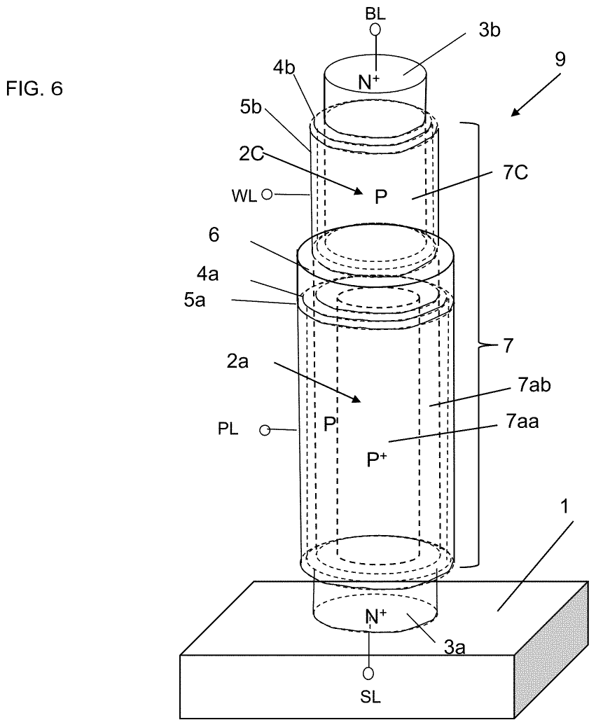

Referring to FIG. 6, the structural view of a dynamic flash memory according to a third embodiment will be described. Note that, in the actual memory device, a large number of dynamic flash memory cells 9 are arranged in matrix on a substrate 1. In FIG. 6, the same or similar elements in FIG. 1 are denoted by the same reference signs.

In plan view, a second Si pillar 7C is formed such that its outer peripheral line is disposed inside of the outer peripheral line of a first Si pillar 2a. The second Si pillar 2C is formed of a P layer 7C. The other configurations are the same as in FIG. 1 and FIG. 5. Note that, in the perpendicular direction, the boundary between the P⁺ layer 7aa and the P layer 7C may be disposed within the insulating layer 6, or in the first Si pillar 2a near the insulating layer 6, or in the second Si pillar 2C.

This embodiment provides the following feature.

In this embodiment, storage of the hole group for writing “1” data is performed in the P⁺ layer 7aa of the first Si pillar 2a. In this case, the first Si pillar 2a having the P⁺ layer 7aa mainly functions as a storage region of the hole group while the second Si pillar 2C formed of the P layer 7C mainly functions as a channel for the switch of reading “1” or “0”. In this case, for example, in a structure in which the first gate conductor layer 5a in an outer peripheral portion around the first Si pillar 2a connects to the gate electrode connecting to the PL line of dynamic flash memory cells arranged in a two-dimensional array on the substrate 1, the outer peripheral line of the first Si pillar 2a is formed outside relative to the outer peripheral line of the second Si pillar 2C, to thereby facilitate formation of the second gate conductor layer 5b connecting to the word line, extending in the first direction, but divided in a direction orthogonal to the first direction. This results in an increase in the degree of integration of the dynamic flash memory.

### Other Embodiments

Note that, in the first embodiment, the gate conductor layer 5a connecting to the plate line PL may be a monolayer or a combination of a plurality of conductor material layers. Similarly, the gate conductor layer 5b connecting to the word line WL may be a monolayer or a combination of a plurality of conductor material layers. The gate conductor layer may, in its outer portion, connect to a wiring metal layer formed of W, for example. The same applies to other embodiments according to the present invention.

In the first embodiment, the first Si pillar 2a and the second Si pillar 2b, which have plan-view shapes that are circular, may have plan-view shapes that are circular, elliptical, or elongated in one direction, for example. Also, in the logic circuit region formed apart from the dynamic flash memory cell region, a combination of Si pillars having different plan-view shapes may be formed, in accordance with the logic circuit design, in the logic circuit region. The same applies to other embodiments according to the present invention.

In FIG. 1, one or both of the first gate conductor layer 5a and the second gate conductor layer 5b may be divided into a plurality of conductor layers. The same applies to other embodiments according to the present invention.

For FIG. 1, the following has been described: the first gate conductor layer 5a may connect to the word line WL and the second gate conductor layer 5b may connect to the plate line PL. Regarding this, in FIG. 5, when the first gate conductor layer 5a connects to the word line WL and the second gate conductor layer 5b connects to the plate line PL, with this, the positional relationship between the first Si pillar 2a and the second Si pillar 2B is reversed. In the SOI, Fin, Nanosheet, or GAA structure, the bit line BL may be connected to the N⁺ layer 3a and the source line SL may be connected to the N⁺ layer 3b. The same applies to other embodiments according to the present invention.

In the description of the first embodiment, during the erase operation, the source line SL is set to a negative bias, to remove the hole group within the channel region 7 serving as the floating body FB; alternatively, instead of the source line SL, the bit line BL may be set to a negative bias, or the source line SL and the bit line BL may be set to a negative bias, to perform the erase operation. Alternatively, other voltage conditions may be employed to perform the erase operation. The same applies to other embodiments according to the present invention.

In FIG. 1, between the N⁺ layer 3a and the first Si pillar 2a, an N-type or P-type impurity layer may be disposed. Between the N⁺ layer 3b and the second Si pillar 2b, an N-type or P-type impurity layer may be disposed. The same applies to other embodiments according to the present invention.

In FIG. 1, the P⁺ layers 7aa and 7ba and the P layers 7ab and 7bb may be formed as layers different in semiconductor materials. The P⁺ layers 7aa and 7ba may be different in acceptor impurity concentration. Similarly, the P layers 7ab and 7bb may be different in acceptor impurity concentration. The same applies to other embodiments according to the present invention.

In the first embodiment, the N⁺ layers 3a and 3b may be formed as layers of another semiconductor material containing a donor impurity. The N⁺ layer 3a and the N⁺ layer 3b may be formed as layers different in semiconductor materials.

In FIG. 1, the boundary between, in the perpendicular direction, the first channel region 7a of the first Si pillar 2a and the channel region 7b of the second Si pillar 2b may be disposed at the position of the insulating layer 6, or in an upper portion of the first Si pillar 2a, or in a lower portion of the second Si pillar 2b. The same applies to other embodiments according to the present invention.

For the present invention, without departing from the broad spirit and scope of the present invention, various embodiments and modifications can be made. The above-described embodiments are provided for the purpose of describing examples of the present invention and do not limit the scope of the present invention. The examples and modifications can be appropriately combined. In addition, the embodiments from which a portion of the features has been removed as needed also fall in the scope of the technical idea of the present invention.

### INDUSTRIAL APPLICABILITY

Semiconductor-element-using memory devices according to the present invention provide high-density high-performance dynamic flash memory.

1. A semiconductor-element-using memory device comprising:
a first semiconductor base disposed on a substrate so as to, relative to the substrate, stand in a perpendicular direction or extend in a horizontal direction, and including a first impurity layer disposed in a region at least including a central portion of a cross section, and a second impurity layer covering the first impurity layer and having a lower impurity concentration than the first impurity layer;
a second semiconductor base connecting to the first semiconductor base;
a first gate insulating layer surrounding a portion of or an entirety of a one-end side surface of the first semiconductor base;
a second gate insulating layer connecting to the first gate insulating layer and surrounding a portion of or an entirety of a side surface of the second semiconductor base;
a first gate conductor layer covering the first gate insulating layer;
a second gate conductor layer covering the second gate insulating layer;
a third impurity layer connecting to the first semiconductor base and having a conductivity opposite to a conductivity of the first semiconductor base; and
a fourth impurity layer connecting to the second semiconductor base and having a conductivity opposite to a conductivity of the second semiconductor base,
wherein voltages applied to the third impurity layer, the fourth impurity layer, the first gate conductor layer, and the second gate conductor layer are controlled to perform a memory write operation, a memory read operation, and a memory erase operation.

2. The semiconductor-element-using memory device according to claim 1, wherein the second semiconductor base includes a fifth impurity layer disposed in a region at least including a central portion in a cross section, and a sixth impurity layer covering the fifth impurity layer, having the same conductive polarity as the fifth impurity layer, and having a lower impurity concentration than the fifth impurity layer.

3. The semiconductor-element-using memory device according to claim 1, wherein the second semiconductor base is formed of a seventh impurity layer having a lower impurity concentration than the first impurity layer.

4. The semiconductor-element-using memory device according to claim 3, wherein, when viewed from a central-axis direction, an outer peripheral line of the first semiconductor base is disposed outside relative to an outer peripheral line of the second semiconductor base.

5. The semiconductor-element-using memory device according to claim 1, wherein a first gate capacitance between the first gate conductor layer and the first semiconductor base is higher than a second gate capacitance between the second gate conductor layer and the second semiconductor base.

6. The semiconductor-element-using memory device according to claim 1, wherein voltages applied to the third impurity layer, the fourth impurity layer, the first gate conductor layer, and the second gate conductor layer are controlled to perform an operation of causing an impact ionization phenomenon due to a current flowing between the third impurity layer and the fourth impurity layer or a gate induced drain leakage current to generate an electron group and a hole group within a channel region constituted by the first semiconductor base and the second semiconductor base, an operation of discharging, of the generated electron group and hole group, the electron group or hole group serving as a minority carrier in the first semiconductor base and the second semiconductor base, and an operation of causing a portion of or an entirety of the electron group and hole group serving as a majority carrier in the first semiconductor base and the second semiconductor base to remain at least in the first semiconductor base, to perform the memory write operation, and
voltages applied to the third impurity layer, the fourth impurity layer, the first gate conductor layer, and the second gate conductor layer are controlled to remove the electron group or hole group remaining and serving as a majority carrier in the first semiconductor base and the second semiconductor base, to perform the memory erase operation.
